(19) United States
(12) Patent Application Publication
(10) Pub. No.: US 2024/0393408 A1
(43) Pub. Date: Nov. 28, 2024

(54) DEVICE FOR CHECKING THE FUNCTION OF A CABLE SHIELD OF A WIRED COMMUNICATION CONNECTION

(71) Applicant: ZF CV SYSTEMS GLOBAL GMBH, Bern (CH)

(72) Inventor: Andreas GOERS, Pattensen (DE)

(21) Appl. No.: 18/685,912

(22) PCT Filed: Aug. 1, 2022
(86) PCT No.: PCT/EP2022/071537

§ 371 Date: Feb. 23, 2024

(30) Foreign Application Priority Data
Aug. 25, 2021 (DE) 10 2021 121 996.5

(51) Int. Cl. G01R 31/58; G01R 31/12

(52) U.S. Cl. CPC G01R 31/58; G01R 31/1272

(57) ABSTRACT

A device for checking the function of a cable shield of a wired communication connection between two communication partners which communicate by the wired communication connection, including a first electrical circuit and a second electrical circuit. The first electrical circuit is provided in at least one of the communication partners, by which a test voltage can be applied to the cable shield. The second electrical circuit provided in one or another of the communication partners, which feeds the applied test voltage to a measured value acquisition unit, which takes a measurement of the test voltage and generates an error signal if a test voltage has been measured that is outside a permissible value range or outside one of a plurality of permissible value ranges.

### CROSS REFERENCE TO RELATED APPLICATIONS

This application is a U.S. National Phase application under 35 U.S.C. § 371 of International Application No. PCT/EP2022/071537, filed on Aug. 1, 2022, and claims benefit to German Patent Application No. DE 10 2021 121 996.5, filed on Aug. 25, 2021. The International Application was published in German on Mar. 2, 2023 as WO 2023/025527 A1 under PCT Article 21 (2).

### FIELD

The invention relates to the technical field of communication between subscriber stations in a wired communication network. The subscriber stations can be electronic processing units or electronic control units.

### BACKGROUND

More and more electronic components that can exchange messages with each other are being integrated into vehicles. For this purpose, various communication networks are formed, which are equipped with gateways that connect the various communication networks with each other. They are used to perform format conversion so that messages in the format of one communication network are converted into the format of the other communication network and vice versa, so that the messages from the electronic components in one communication network are also understood by the electronic components in the other communication network and vice versa. In some cases, however, control units that load the communication bus very heavily are networked in a separate branch, even though the same bus system is used and no format conversion is required for this branch.

In recent years, the electronic control units have mostly been networked with each other by the CAN bus system, corresponding to Controller Area Network. This was standardized in 1994 in the ISO standard ISO 11898-1. In the meantime, various enhancements to the CAN bus protocol have been standardized. What all these variants have in common is that the physical transmission medium is a twisted two-wire cable without shielding. The bus topology of the CAN bus corresponds to a line structure. This makes multipoint connections possible, as up to 128 bus stations can be connected to the common bus line. This is a not insignificant advantage. The bus cables can be laid very flexibly. The length of the cables is drastically reduced due to the linear bus structure and this results in a considerable weight saving. One disadvantage, however, is that the achievable data transfer rate is relatively low. Even with the extended variant according to the CAN-FD, only data transfer rates in the range of up to 5 Mbit/s are possible.

Today, in addition to control units, sensors and actuators, which are primarily networked via a CAN bus, other electronic components are also used in vehicles. Examples include onboard communication units, central computing units, gateways, infotainment units such as radios, telephones, and display units, navigation units, etc. In addition, imaging sensors such as radar, lidar, camera and ultrasound devices are also mentioned. Such devices can have an increased volume of data or produce an increased volume of data.

The data transport capacity of the CAN bus is often no longer sufficient for this. For this reason, other communication technologies are used to network such devices. In particular, communication networks based on Ethernet technology are mentioned here. In the automotive sector, MOST, corresponding to “Media Oriented System Transport”, and BroadR-Reach, the further development of which is currently taking place under the title “Automotive Ethernet”, are mentioned in particular. These communication systems offer data rates of 100 Mbps and more, are designed to increase data throughput and reduce the weight and cost of cabling. In particular, the variant according to the IEEE 802.3bw standard, also known as 100 Base-T1, was developed according to the requirements of automotive systems. All that is required is an unshielded cable with only one pair of twisted wires, through which the data can be transmitted symmetrically in both directions in full-duplex mode over a distance of 15 m.

In 2016, the 1000Base-T1 variant, in which the data rate could be increased to 1 Gbit/s, was even specified for use in vehicles and industrial applications. The data are also transmitted via a cable with only one twisted two-wire line. For the maximum length of 15 m, the cable specification does not specify shielding for the cable. This corresponds to the so-called type A cable. In addition, there is also the type B cable, which may have a length of up to 40 m. However, shielding is recommended for this communication channel. The standard for the 1000Base-T1 variant is IEEE 802.3 bp. Shielding greatly improves the EMC properties, such as radiation and interference of the communication line, so that the quality requirements for the twisted cable in the shield are significantly lower. For this reason, shielded cables (type A cables with cable lengths of up to 15 m) are often used in the automotive sector, even for shorter transmission distances, as they offer better interference immunity and have no significant economic disadvantages.

For applications in the field of autonomous driving, including driver assistance systems, in which automatic driving functions are also used, the volume of data is so large that communication connections based on 1000Base-T1 are increasingly being used. In the commercial vehicle sector, there is also the fact that electronic components that have to work together are located in both the towing vehicle and the trailer vehicle. There is therefore one communication network for the electronic components in the towing vehicle and another for the components in the trailer vehicle. When the trailer vehicle is connected, the two communication networks are connected to each other via plug-in contacts. A gateway device can be installed in the towing vehicle and in the trailer vehicle, between which a communication connection must be established when coupling. For this purpose, part of the bus cable is housed in a spiral-shaped plastic sheath on the trailer vehicle. The cable plug is plugged into the corresponding socket of the towing vehicle. Conversely, this spiral cable is plugged into a socket on the trailer vehicle. This creates a very flexible connection that cannot break off even if the trailer vehicle swivels out to a greater extent. The cable is extended accordingly by the spiral shape. Because the gateway of the trailer vehicle may be located at the very back of the trailer vehicle, such as near a rear-mounted rearview camera, a second part of the cable may extend the length of the trailer vehicle. This can result in cable lengths of more than 15 m for coupling the communication networks for these bus cables.

The shielded cables recommended in the 1000Base-T1 standard are of the shielded twisted pair type. There are a plurality of different types of shielded cables available. A particularly high-quality shielded cable is known as S/FTP. This means that the cables are double shielded. They contain a twisted two-wire cable. This is covered with an aluminum foil. In addition, the aluminum foil is covered with a wire mesh. The double shielding is therefore made of aluminum foil and wire mesh. Finally, the cable constructed in this way is ALSO encased in a plastic layer. FIG. 1 shows the S/FTP cable constructed in this way. The English name is: “screened foiled twisted pair”. The reference sign TP refers to the twisted, isolated pair of wires. The single wire is denoted by the letter A. Plastics, especially polyethylene, are used as insulating material for the individual wires. The respective wire insulation is marked with the letter I. The letter F marks the aluminum shielding foil. The wire mesh is marked with the reference sign SD. The wire mesh SD is made of metal. A steel alloy is often used. For high-quality cables, the wire mesh can be made of copper. The plastic sheath of the cable STP is denoted by the reference sign M. Typical plastics used here are propylene, polyurethane, or polyethylene.

One problem, however, is that the cable shield is sensitive. First of all, it is necessary that the cable shield must be connected to the vehicle ground in order to avoid static charging. FIG. 2 shows this principle. The reference sign CU1 is used to designate a first electronic control unit. The reference sign CU2 is used to designate a second electronic control unit. Instead of electronic control units, electronic processing units can also be used, which do not cause any control processes. The two electronic control units CU1 and CU2 are connected to each other via the cable STP. It is an S/FTP cable. The twisted pair of wires is marked with reference sign TP. The outer shield in the form of a wire mesh is designated SD. The inner shielding foil that encloses the pair of wires TP is not shown. Also not shown is the plastic sheath, which protects the wire mesh from external influences and mechanical damage. The cable is provided with plugs at both ends. The plugs are plugged into the corresponding socket of the respective control unit. The respective socket is mounted on a board that also contains a transceiver device for the 1000Base-T1 Automotive Ethernet protocol. This transceiver device for the control units CU1 and CU2 is designated with reference sign TSC in FIG. 2. It is a component in the form of a semiconductor chip, which is referred to as the “Medium Dependant Interface” in Ethernet. The task thereof is to convert the symbols to be transmitted into symmetrical differential voltage values, which are applied to the two wires of the twisted pair of wires to transmit the symbols. This is carried out when the data are sent. Conversely, in the transceiver devices TSC1 and TSC2, the symmetric differential voltage values are measured and converted into symbols. This is carried out when receiving data. As mentioned, the 1000Base-T1 standard has been designed so that the two communication partners can send and receive data at the same time (full-duplex operation). To do this, the transmitting bus station adds its own voltage value for the respective wire to the voltage applied there; while as a receiver it subtracts its own voltage from the voltage applied in each case. The result of the subtraction then corresponds to the voltage sent by the opposite bus station. The type of modulation used to convert the data into bus signals is called three-level pulse amplitude modulation and abbreviated to PAM3.

For the other processing of the data, i.e. from the data security layer upwards, each station contains a microcomputer, which is connected to the transceiver module TSC via a digital interface. In the control unit CU1 and in the control unit CU2, the microcomputer is designated with the reference sign MCU. In control units, microcontrollers are typically used as microcomputers.

A problem with the arrangement in FIG. 2 can be the application of the cable shield SD to the device ground. If there are potential differences between the two control units CU1 and CU2, the so-called ground offset, a compensating current flows over the cable shield SD. As a result, the cable shield can be damaged or even destroyed. If the two control units CU1 and CU2 are each housed in different parts of the vehicle, such as the towing vehicle and the trailer, there is practically always a ground offset. A typical value for the ground offset between the towing vehicle and the trailer vehicle is approx. 2 V.

What must also be avoided are so-called sheath waves, which can occur with shielded cables if there is a mismatch when the cable is connected. This is very problematic for electromagnetic compatibility, as sheath waves that occur lead to the radiation of RF energy, which can then interfere with the function of the electronic components in the vehicle or in the environment. In order to avoid such RF interference, it is customary to capacitively couple the shielding of the cable STP to the vehicle ground. An example of such a circuit is shown in FIG. 3. There, in each control unit CU1 and CU2, a parallel connection of a resistor R2 with a capacitor C1 is connected on the one hand to the cable shield SD and on the other hand to the vehicle ground. The capacitor C1 causes RF interference to be shorted to ground, while the resistor R2 limits the current that can flow out via the cable shield SD in the event of static charges or an offset between the ground potential of the towing vehicle and the ground potential of the trailer vehicle. However, the actual shielding effect of the shielding SD of the cable STP is only achieved as long as the shielding is correctly contacted at both communication partners CU1 and CU2. If the contact on one or both sides is no longer achieved, sheath waves can propagate again and it can lead to an influence on the communication path but also to increased radiation and interference with other components.

There is therefore a need to monitor the correct functioning of the cable shield. Especially in the case of frequent plugging operations, in which the cable plug PL is plugged into a connection socket SC, as is necessary when coupling a trailer vehicle to a towing vehicle, twisting and bending can cause the contacting of the shielding, usually in the area of the plug PL, to deteriorate. This can lead to a complete loss of contact.

### SUMMARY

In an embodiment, the present disclosure provides a device for checking the function of a cable shield of a wired communication connection between two communication partners which communicate by the wired communication connection, comprising a first electrical circuit and a second electrical circuit. The first electrical circuit is provided in at least one of the communication partners, by which a test voltage can be applied to the cable shield. The second electrical circuit provided in one or another of the communication partners, which feeds the applied test voltage to a measured value acquisition unit, which takes a measurement of the test voltage and generates an error signal if a test voltage has been measured that is outside a permissible value range or outside one of a plurality of permissible value ranges.

### BRIEF DESCRIPTION OF THE DRAWINGS

Subject matter of the present disclosure will be described in even greater detail below based on the exemplary figures. All features described and/or illustrated herein can be used alone or combined in different combinations. The features and advantages of various embodiments will become apparent by reading the following detailed description with reference to the attached drawings, which illustrate the following:

FIG. 1 shows the basic design of an S/FTP Ethernet cable;

FIG. 2 shows a first block diagram for connecting two electronic control units via a shielded Ethernet cable;

FIG. 3 shows a second block diagram for connecting two electronic control units via a shielded Ethernet cable;

FIG. 4 shows a towing vehicle and a trailer vehicle ready for pick-up in the form of a semi-trailer;

FIG. 5 shows a third block diagram for connecting two electronic control units via a shielded Ethernet cable;

FIG. 6 shows a first voltage evaluation diagram, which shows different possible ranges of measured values when testing the function of the cable shield and the meaning thereof;

FIG. 7 shows a fourth block diagram for connecting two electronic control units via a shielded Ethernet cable;

FIG. 8 shows a representation of a type of capacitive coupling of the cable shield to ground potential;

FIG. 9 shows a fifth block diagram for connecting two electronic control units via a shielded Ethernet cable;

FIG. 10 shows a second voltage evaluation diagram, which shows different possible ranges of measured values when testing the function of the cable shield and the meaning thereof;

FIG. 11 shows a sixth block diagram for connecting two electronic control units via a shielded Ethernet cable;

FIG. 12 shows a third voltage evaluation diagram, which shows different possible ranges of measured values when testing the function of the cable shield and the meaning thereof; and

FIG. 13 shows a block diagram for electronic components of a towing vehicle and electronic components of a trailer vehicle, which are connected to each other via shielded Ethernet cables.

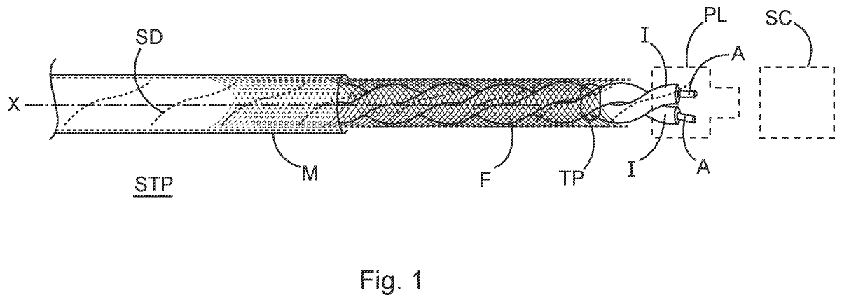

### DETAILED DESCRIPTION

In an embodiment, the present invention provides a device with which it is possible to check the correct effect of the shielding of the connecting cable.

In an embodiment, the invention relates to a device for checking the function of a cable shield of a wired communication connection between two communication partners which communicate by means of the wired communication connection. The special design consists in the fact that a first electrical circuit, by means of which a test voltage is applied to the cable shield, is provided in at least one of the communication partners, while a second electrical circuit, which supplies the applied test voltage to a measured values acquisition means, is provided in one or the other of the communication partners, wherein the second electrical circuit takes a measurement of the test voltage and generates an error signal if a test voltage has been measured that is outside a permissible range of values or outside one of a plurality of permissible ranges of values. With the increasing bandwidth requirements for communication between electronic devices, the interference immunity of communication can only be maintained by using shielded, or better still double-shielded, cables. However, this is an additional source of failure. This is because the shielding must be connected to ground potential so that static charges and RF interference can be dissipated. This type of contacting of the shield takes place in the area of the connector in the case of pluggable connection cables. Over time, this can lead to fractures in the sensitive shielding with frequent plugging operations. This poses a risk, at least for safety-relevant electronic systems, because the cable shield only works correctly if the shield is correctly contacted. Here, an embodiment of the invention offers a way to increase safety and reliability. With an embodiment of the invention it is possible to monitor the correct function of the shield during operation and to issue an error message or a warning message if a loss of the contact is detected. The cost for this monitoring is low because the test voltage can be supplied to the cable shield with just a few switching elements. It is possible to measure the test voltage with the microcontroller, which is usually available with the respective electronic device anyway. The evaluation of the measured voltage and the generation of the warning message can be carried out with the help of an additionally installed computer program that is installed in the electronic device.

In an embodiment, switching devices that can switch the application of the test voltage on and off are provided in the first electrical circuit. At the same time, switching devices can be provided in the first electrical circuit that can switch on and off the dissipation of the test voltage to the electrical ground. This offers a high degree of flexibility for the execution of the test. This also makes it possible not to permanently apply the test voltage to the shield. In this way, the test can be applied in a phase where the electronic devices have not yet reached a critical operating state. This also improves the ability to troubleshoot. If a resistance value is absent due to non-connection during the measurement, the measured test voltage changes, so that a statement can be made that the electronic device in which the resistor should have been connected has a fault state.

In this case, it is preferable that one or both communication partners contain electronic control devices that are used to control the first or second switching device.

In addition, it is advantageous in this respect if the electronic control devices are programmable control devices, which are implemented in particular as microcontrollers. These offer the possibility of programmability, so that the performance of the test phase can be very variable and optimized for changing requirements.

At the same time, microcontrollers usually offer an integrated analog/digital converter as a means of measured value acquisition, which can be used to acquire the test voltage and make it available in digital form for evaluation.

For the device according to an embodiment of the invention, it is also advantageous if in the first electrical circuit contact pins are distributed around the circumference of the cable shield, which press against contact surfaces of the cable shield in the area of the connector of the cable of the communication connection, when it is plugged into the corresponding socket of the communication partner, wherein the contact pins are connected to ground potential by respective capacitors (C1a-C1d) which have different capacitance values. As a result, the contact with the cable shield is maintained when individual contact pins or contact surfaces are worn. By selecting the capacitance values, it is possible to prevent the formation of an absorption circuit which would only dissipate certain signal frequencies to ground.

In addition to shielding, a preferred type of embodiment of the cable of the communication connection has a number of twisted pairs of wires through which the bus signals are transmitted. Such cables have proven themselves in many ways for the reliable transmission of data, because common-mode interference is suppressed by the twisting of the wire pairs.

For use in commercial vehicles, it can be advantageous if the cable of the communication connection is even a single shielded cable of type STP or a double shielded cable of type S/FTP, corresponding to “screened foiled twisted pair” according to the standard ISO/IEC-11801 (2002) E: S/FTP with only one pair of twisted wires, sheathed with aluminum foil and a wire mesh as an external shield. In addition, other variants of shielded cables are also approved for use in the commercial vehicle sector.

In this respect, it is also advantageous if the data transmission through the cable of the communication connection is carried out according to the communication standard IEEE 802.3 bp, corresponding to 1000Base-T1: Type B. This allows data to be transmitted at a data rate of 1 Gbit/s and, if necessary also with higher data rates.

In an embodiment, the invention relates to a method for checking the function of a cable shield of a wired communication connection between two communication partners communicating via the wired communication connection. This method is characterized by the following steps: applying a test voltage to the cable shield by one communication partner, measuring the test voltage at the cable shield by one or the other communication partner, evaluating the measured values by one or the other communication partner and generating an error signal by one or the other communication partner if a test voltage has been measured that is outside an allowed range of values or outside one of a plurality of allowed ranges of values. This method offers the advantages corresponding to the device according to embodiments of the invention. With the method according to an embodiment of the invention it is possible to monitor the correct function of the shield during operation and to issue an error message or a warning message when the loss of the contact is detected. Here the cost of this type of monitoring of the function of the cable shield remains low.

In an embodiment, the invention relates to an electronic processing unit for use as a communication partner in a device according to embodiments of the invention. In this electronic processing unit, a first electrical circuit is provided by which a test voltage can be applied to the cable shield. Alternatively or additionally, a second electrical circuit is provided that feeds the applied test voltage to a measured value acquisition means, which takes a measurement of the test voltage and generates an error signal if a test voltage has been measured that is outside a permissible value range or outside one of a plurality of permissible value ranges. This means that the cost of implementing the cable monitoring for a station can be varied. For full flexibility in carrying out the test, both electrical circuits can be provided in both communication partners. In principle, however, it is sufficient if the first circuit is provided in one of the communication partners and the second electrical circuit in the other communication partner. In this way, the cost required to implement the test can be limited to individual electronic devices.

An advantageous extension is that switching devices are provided in the first electrical circuit that can switch the application of the test voltage on and off and/or switching devices are provided in the first electrical circuit that can switch the dissipation of the test voltage to the electrical ground on and off. These can preferably be electronic switches, for example transistors. With this variant, the testing possibilities are extended. This allows different voltage levels to be applied to the cable shield. This can be used to signal various additional information. In the event that communication via the communication connection fails, the voltage level on the cable shield can be used to signal the status of the control unit connected on the opposite side. One example concerns the signaling of the information that the safety-relevant functions are available in the control unit and continue to be carried out autonomously. For the signaling of this information, an additional line (ABS fault indication) is provided for this purpose in the case of brake control units currently used in trailer vehicles or PLC communication, corresponding to powerline communication, is prescribed. These solutions can be replaced by the measure described here.

Here it is particularly advantageous if the electronic processing unit contains an electronic control device that is used to control the first or second switching device. This electronic control device can be implemented as a programmable control device, in particular in the form of a microcontroller. Such electronic devices are typically equipped with microcontrollers, so there is no additional cost involved.

This also offers the possibility as an extension to signal more additional information on the cable shield, for example by (slow) switching of a plurality of switches, wherein different voltage levels can be applied at different intervals by connecting different resistors, which signals different information.

In turn, it is advantageous for the electronic processing unit if the cable shield is connected to ground potential at a plurality of points with capacitors that have different capacitance values distributed over its circumference. This minimizes the negative influence of conductor paths. Due to the special choice of capacitance values, it is possible to prevent the formation of an absorption circuit, which would only dissipate certain signal frequencies to ground.

An embodiment of the invention consists of a vehicle consisting of a towing vehicle and a trailer vehicle, wherein the vehicle has a device according to embodiments of the invention, wherein one communication partner is an electronic processing unit in the towing vehicle and the other communication partner is an electronic processing unit in the trailer vehicle, both of which communicate with each other via the cable of the communication connection.

Exemplary embodiments of the invention are shown in the drawings and are explained in more detail below on the basis of the figures.

The present description illustrates the principles of the disclosure according to embodiments of the invention. It will therefore be understood that persons skilled in the art will be able to conceive various arrangements which, although not explicitly described here, embody principles of the disclosure according to embodiments of the invention and are also intended to be protected in their scope.

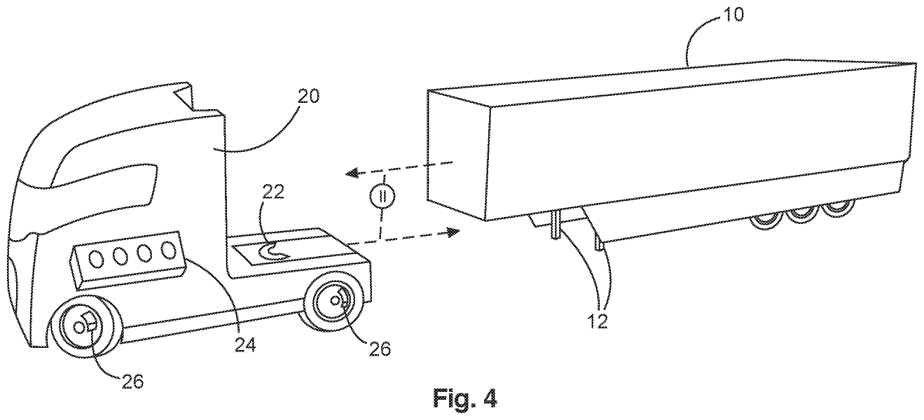

FIG. 4 shows a towing vehicle 20 aligning with a trailer vehicle 10 ready for pick-up. The term trailer vehicle 10 is understood here to mean a trailer vehicle that is equipped with a coupling system for a towing vehicle 20. These are mainly commercial vehicle trailers. These are often equipped as semi-trailer vehicles with a coupling system in which a so-called king pin of the trailer vehicle 10 is guided into a fifth wheel plate 22 of the towing vehicle until it clicks into place, creating a rotatable connection between towing vehicle 20 and trailer vehicle 10. However, it can also be other trailer vehicles, such as trailers used in agriculture or trailers that are attached to construction vehicles. Larger caravans, as well as leisure and sports trailers, are also considered.

The towing vehicle 20 is a commercial vehicle in the form of a semi-trailer tractor. Here, too, other towing vehicles can also be considered. Other examples include tractors used in agriculture, construction vehicles or camping vehicles. Finally, it is mentioned that the list is not an exhaustive list. Thus, passenger cars are also used as towing vehicles, which can also be equipped with the subject-matter of embodiments of the invention. The term towing vehicle is also used here only as an example. Embodiments of the invention can also be used in other vehicles that are not used as towing vehicles. This includes buses and construction and harvesting machinery, as well as motorcycles, military vehicles, robots, ships, aircraft and drones. Furthermore, the use of embodiments of the invention is not limited to its use in vehicles or mobile devices. Embodiments of the invention can also be used in industrial plants, in building automation, in machine control as well as in process and plant control.

The towing vehicle 20 is equipped with a drive unit 24, which corresponds to an internal combustion engine in the form shown. Of course, other types of drive units can also be integrated into the towing vehicle. Other examples include electric motors and fuel cells. In the case of the wheels of the towing vehicle 20, the service brakes 26 are also highlighted.

The trailer vehicle 10 stands on supports 12, which are folded in or raised after coupling to a towing vehicle. The driver of the towing vehicle 20 still has to connect the connecting cables between the trailer vehicle 10 and the towing vehicle 20 for the electrical systems and the pneumatic systems and, if appropriate, the hydraulic systems. In the case of modern trailer vehicles 10, a cable must also be plugged in for communication between the on-board electronics of the towing vehicle 20 and the on-board electronics of the trailer vehicle 10. In the future, the use of Automotive Ethernet in the 1000Base-T1 variant is planned for this communication connection. The specification of this communication standard is available under the number IEEE 802.3 bp. Reference is therefore made to this standard for further details, including with regard to the present disclosure. A shielded Ethernet cable, for example the S/FTP cable described above, is used as a cable for this, which contains a twisted pair of wires as a communication line and has double shielding in the form of aluminum foil plus wire mesh.

Today, when coupling trailers, the pneumatic, hydraulic and electrical connecting cables are usually still connected by hand. This task falls to the driver. In the future, starting in the yard area, i.e. at the depots of logistics companies, etc., there will be automated towing vehicles 10, which will take over the maneuvering of trailer vehicles 20 without driver intervention. For this purpose, coupling systems are being developed that allow trailer vehicles to be coupled automatically. In such coupling systems, which will have a similar design to automatic coupling systems in railway transport, there is also a connector in the coupling unit for connecting the shielded Ethernet cable. The coupling unit will be positioned near the kingpin on semi-trailer trailers. During the coupling process, all electrical, pneumatic, and, if appropriate, hydraulic lines will be connected automatically.

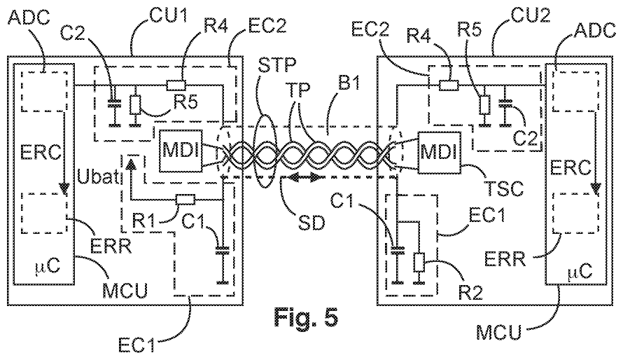

FIG. 5 shows an embodiment in which the circuits EC1 of the control unit CU1 and the circuit EC1 of the control unit CU2 have been particularly simplified. In the circuit EC1, the battery voltage Ubat is supplied to the cable shield SD via the connection of the battery voltage Ubat and a resistor R1. At the same time, a capacitor C1 is connected to ground from the cable shield. In the commercial vehicle sector, the battery voltage is typically 24 V. Recently, even 48 V batteries have been used. The circuit EC1 of the control unit CU2 consists of a parallel connection of a resistor R2 and a capacitor C1, which is connected to the cable shield SD. The voltage divider, which supplies the test voltage to the cable shield SD, consists only of the resistors R1 and R2. If the resistors R1 and R2 are of the same size, the test voltage at the cable shield will be set to Ubat/2 V. If the contacting of the cable shield SD is missing at any point on the cable, the measured voltage in CU1 rises to a value of approx. 80% of Ubat or more and is thus in the upper error range. An error message ERC is then generated and an entry is set in the error memory ERR of CU1. In this fault case, the test voltage can no longer be supplied and a voltage value in the lower error range is measured in CU2, which extends up to a value of 20% of Ubat V. The error message is also output and the entry is set in the error memory ERR of the control unit CU2.

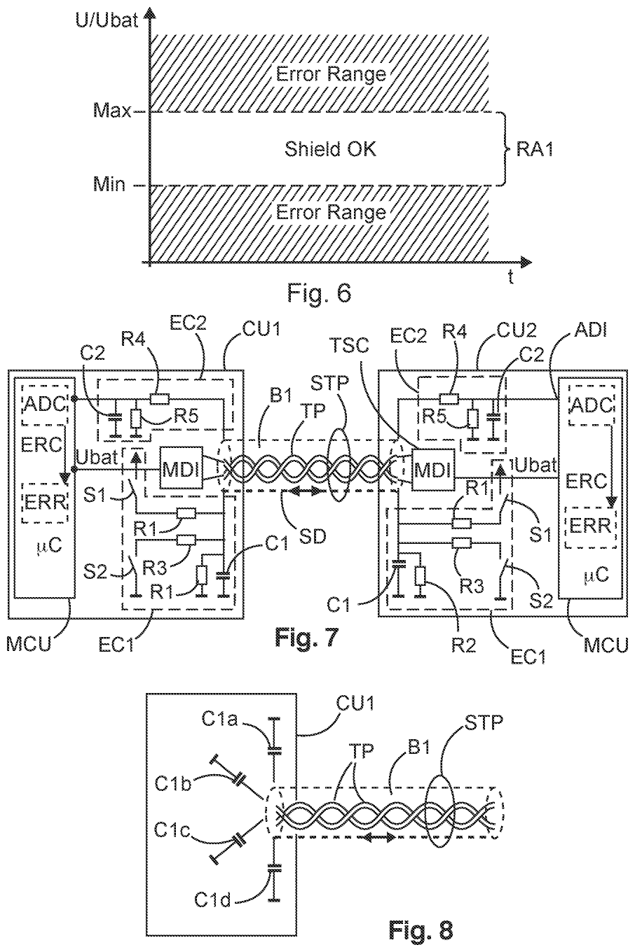

FIG. 6 shows the permissible range for voltage measurement at the cable shield when performing the test with the circuit according to FIG. 5. The permissible voltage range is marked with the reference sign RA1. This permissible voltage range is symmetrical around the voltage value Ubat/2. The value Min shown corresponds to the value of 20% of Ubat. The value Max corresponds to the value of 80% of Ubat. The microcontroller MCU generates the respective error signal ERC, which is entered into the error memory ERR. The two voltage ranges at which an error is detected are referred to as the Error Range in FIG. 6.

FIG. 7 shows an embodiment according to the invention for a circuit with which it is possible to determine the voltage level applied to the cable shield SD only at runtime. With this solution, either the connection of the cable shield SD in the control unit CU1 or in the control unit CU2 can be switched to ground or alternatively to Ubat with high impedance. This makes it possible to react flexibly to line connections.

In the case of automotive Ethernet, it is necessary to determine which communication partner should work as a so-called “master” and which communication partner as a so-called “slave”. This serves to start and maintain synchronization between the communication partners. In the following, the device configured as “Master” is referred to as the primary device, and the device configured as “Slave” is referred to as the secondary device. The primary device has the function of sending symbols on a regular basis, which the secondary device uses to synchronize.

To determine which device is set as the primary device or secondary device, the Automotive Ethernet standard specifies a so-called autonegotiation process. This process is linked to which reference potential is placed on the shield resistor for which electronic control unit. In this way, it is then achieved that the switches automatically assume the correct state when the control units are switched on, according to the negotiated configuration as a primary or secondary device. The cable used to connect the two control units CU1 and CU2 is a double-shielded S/FTP cable with a pair of twisted wires in both the exemplary embodiments shown in FIG. 5 and FIG. 7. In the same way, a single shielded STP cable with a twisted pair of wires could be used as an alternative. The shield that will be contacted should be in the form of a wire mesh.

As part of the various Ethernet variants, there are other cable types that are equipped with shielding. Examples include S/UTP, F/FTP, U/FTP, SF-FTP, S/STP, F/STP. All these types of cables are equipped with one or more twisted pairs of wires, or “twisted pairs”, through which the bus signals are transmitted. In the STP and FTP cable types, the twisted pairs are individually shielded with aluminum foil. The preceding letter indicates the type of overall shielding of the respective cable type. S stands for a braided shield, F for a foil shield and SF for a braided and foil shield. In addition, there are also so-called quad pair cable types, in which four wires are twisted together.

In the exemplary embodiment of FIG. 7 shown, the same reference numbers denote the same components as in the preceding FIG. 5. To test the proper functioning of the cable shield, a first circuit EC1 is provided for the control unit CU1 and a second circuit EC2. Both circuits EC1 and EC2 can be built in discrete form on a printed circuit board (PCB). SMD components are preferably used for the implementation of circuits EC1 and EC2. The circuit EC1 consists of the components connector Ubat for the battery voltage for applying the supply voltage to the circuit EC1, an electronic switch S1, a first resistor R1, a capacitor C1, a second resistor R2 connected to a ground potential, a second electronic switch S2 and a third resistor R3. An additional circuit EC2 is provided for the detection of the test voltage. This consists of the components capacitor C2, resistor R4 and resistor R5. The cable shield SD is contacted with the resistor R4. This leads the potential of the cable shield to an AD input ADI of the microcontroller MCU. The function of resistor R5 and capacitor C2 corresponds to the function of resistor R2 and capacitor C1 of circuit EC1. The analog voltage present there is detected by the AD converter ADC contained in the microcontroller MCU1. The same circuits EC1 and EC2 can also be included in the control unit CU2 but are not mandatory.

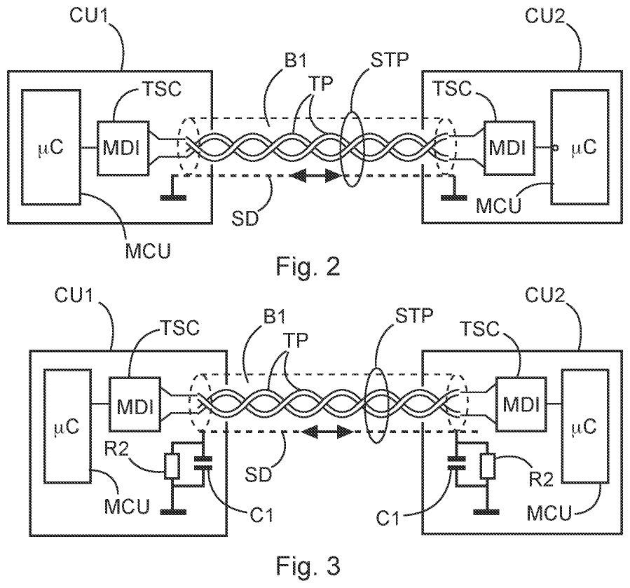

The function of circuits EC1 and EC2 in FIG. 7 is explained below. With the help of circuit EC1, as explained in FIGS. 2 and 3, as before the function is fulfilled that the cable shield SD is capacitively coupled to ground potential. Capacitor C1 is used for this purpose. Static charges and direct currents are also dissipated to ground via R2. The switches S1 and S2 can now be used to set different voltage levels. The switches S1 and S2 are preferably implemented as electronic switches, for example in the form of transistors. Bipolar transistors are particularly suitable for this purpose. Alternatively, field-effect transistors can be used. The transistor used is operated as a controllable switch. The control signal is supplied to the transistor by the microcontroller MCU. Switching the switches S1 and S2 on and off can thus be microprocessor controlled.

FIG. 8 shows a special way of contacting the cable shield for capacitive coupling to ground potential. Contacting the cable shield SD takes place In the area of the plug PL of the connection cable STP. For this purpose, a plurality of contact surfaces are usually provided in the plug PL, which are distributed around the circumference of the cable STP and establish a connection with the shield SD, i.e. the wire mesh. The pins are connected to each other in a ring. The dissipation resistors R2 can still be connected in parallel with the capacitive connection. In order to prevent the wiring with a capacitor in conjunction with the inductance of the cable from creating an absorption circuit that would only dissipate frequencies in the range of the resonant frequency, a plurality of capacitors, for example the depicted capacitors C1a-C1d, are placed and dimensioned differently. The capacitances of the capacitors are preferably selected from the range of 100 pF to 100 nF.

In order to obtain full flexibility for monitoring the shielding, both control units CU1 and CU2 can be equipped with the same circuits EC1 and EC2. However, the test voltage should only be fed into one side of the cable STP per test procedure. Therefore, it is envisaged that the control units CU1 and CU2 will be configured in an appropriate manner. This can be done by means of software. When the software is installed, it can also specify whether the control unit should be configured as a primary device or as a secondary device for monitoring the cable shielding. In the example of FIG. 7, it is now assumed that the control unit CU1 is configured as the primary device and the control unit CU2 as the secondary device. As a result, during the performance of the test, the switch S1 on the control unit CU1 is closed in order to supply the test voltage from the control unit CU1 from the shield SD of the cable STP. The switch S2 remains open on the control unit CU1. On the other hand, the control unit CU2 is configured in such a way that when the test is performed, switch S1 is opened and switch S2 is closed. The test voltage which should be measured when the shield is working then results from the divider ratio according to which the voltage divider consisting of resistor R1 and the parallel connection of resistors R2 of control unit CU1 with R2 and R3 of control unit CU2 divides the applied voltage Ubat. The resistors R1 to R3 should be high impedance so that no higher currents can flow via the shield. As an example, the resistors are dimensioned differently. An example is the dimensioning of the resistors with R1 equal to 100 kΩ, R2=300 kΩ and R3=300 kΩ with a supply voltage of Ubat=24 V, a test voltage of Ubat/2=12 V. The test voltage is measured during the test phase. It can be measured in both control units CU1 and CU2.

In one variant the test phase can always be carried out at the same time after switching on the control units CU1 and CU2 as part of the boot process. The test evaluation is carried out by a program that is processed by the microcontroller MCU. After the measured value acquired by the AD converter ADC is available, it is evaluated. This is carried out as shown in FIG. 7. If the shield SD is correctly contacted both by the control unit CU1 and the control unit CU2, the test result should be a test voltage of Ubat/2. However, if there is a fault with the control unit CU2 and it could not be started, the fact that the switch S2 on the control unit CU2 could not be closed should result in a different measured value as the test result. In this case, the resistor R3 is missing in the parallel connection of the resistors. Thus, only the two resistors R2 are connected in parallel. Due to the different divider ratio, the measured value should then result in a voltage value of approx. 2/3Ubat V. In both cases, the test proves that the shield is correctly contacted and functional. In the first case, it can even be said that the control unit CU2 has also been properly started and is in operation. In the second case, it can be said that the control unit CU2 has an error state, because the test shows that it was not started properly. If the shield is not properly contacted by the control unit CU2, the resistor R2 on the control unit CU2 will also become inactive. The ratios of the voltage divider also change as a result. Now only the resistors R1 and R2 are acting on the control unit CU1 side. This results in a measured test voltage of approx. 75% of Ubat. This is outside the tolerance range for the test voltage measured values shown in FIG. 6 and an error in the contacting is thereby detected. The evaluation program will store this error in the error memory ERR of the microcontroller MCU. When the control unit CU1 is used in a vehicle, an error message can also be sent via the on-board communication network to a display device, which displays the error message. If the cable being checked is the cable used to connect the communication networks between the towing vehicle 20 and the trailer vehicle 10, the driver can check the plug connection of the connected cable after detection of the error message. If the fault cannot be corrected by reinserting the plug of the connection cable, the driver should visit a workshop as soon as possible to have the defective cable replaced.

Other fault conditions that are detected can be differentiated if it is also evaluated whether communication via the connection cable STP is possible.

If no communication is possible and the resistor R3 is switched off at control unit CU2, this means that the control unit CU2 is in a fault state.

If no communication is possible and the resistor R3 is switched on at control unit CU2, it means that the control unit CU2 has been started correctly, but no communication is possible. In this case, the control unit CU2 should switch itself to a safety state in which it performs a safety function for itself. In the case of a brake control unit that is located in the trailer vehicle 10, this means that the control unit assumes a state in which it offers an independent ABS function, in which it only relies on the measured values of the wheel speed sensors and, if appropriate, other sensors of the trailer vehicle 10.

There is no communication via the cable STP and the additional resistor R3 is not switched on in both control units CU2, which means that there is a double fault and the starting process in both control units CU1 and CU2 was faulty. Both control units can be restarted to try to see if the error can be corrected.

Alternatively, the test can also be repeated a plurality of times during operation at certain intervals or according to certain operating conditions. Thus, it is possible to detect the loss of contact of the shielding of the cable STP while still in operation. This is advantageous in the vehicle sector, as well as in machine and plant controls, because it is possible that a loss of contact occurs due to a variety of shocks and vibrations.

The tolerance range for the evaluation of the measured voltage extends in the range between the Min and Max values shown in FIG. 6.

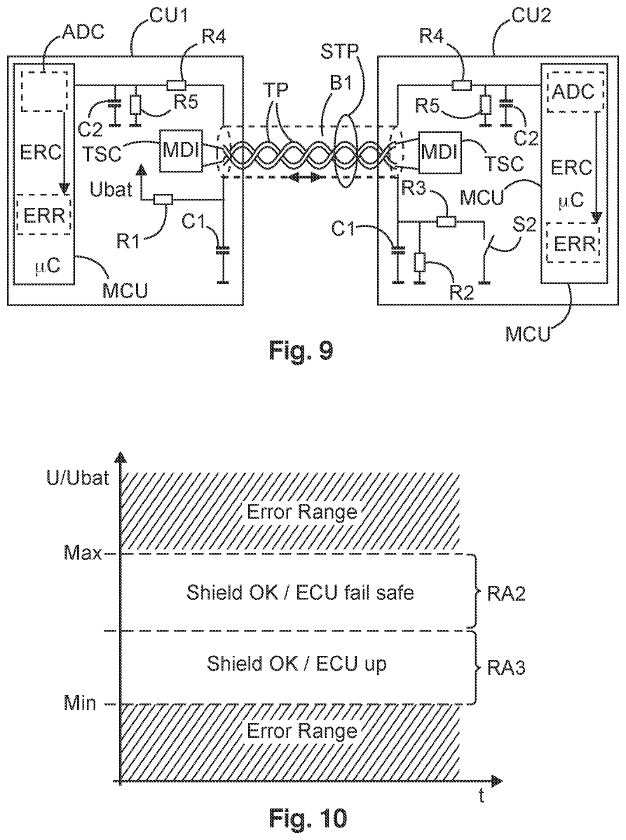

An exemplary embodiment of the invention is explained below. FIG. 9 shows an embodiment in which the circuit EC1 in control unit CU1 is designed differently from the circuit EC2 in control unit CU2. At the same time, the circuits EC1 have been simplified. In circuit EC1 of CU2 the resistor R1 and the switch S1 and the connection to Ubat have been omitted. In the circuit EC1 of control unit CU1, the switch S1 has been omitted and the resistors R2 and R3 and the switch S2 have been omitted. In this way, the test voltage is permanently applied to the cable shield SD via resistor R1. Through this variation of the circuits EC1, the control unit CU1 is permanently configured as the primary control unit in relation to the cable shield SD test. The control unit CU2 is thus permanently configured as a secondary control unit with regard to the cable shield SD test. In this way, the function of the cable shield can still be checked, while the assessment of the status of the control units is no longer possible on the basis of the switching on and off of the resistors R1 and R2 by the switches S1 and S2.

FIG. 10 shows the special way of evaluating the measurement result when performing the test in the case of the circuit according to FIG. 9. In this case, the permissible voltage range RA1 is divided into two ranges RA2 and RA3. In the case where R1 and R2 act in parallel with R3 (normal operating case), the ratio is 1 to 1.5. Accordingly, the measured voltage in this case is a value of approx. 2/3 Ubat V. If the shield on the side of the control unit CU2 is no longer contacted, the effect of the resistors R2 and R3 is lost. Thus the measured voltage on the shield will tend towards Ubat because of the pull-up resistor R1. The measured voltage will therefore be in the upper error range area. The fault is then detected, an error signal ERC is output, and an entry is placed in the fault memory ERR in control unit CU1. If, on the other hand, the contacting of the shield on the side of the control unit CU1 is missing, the measured voltage on the side of the control unit CU1 is still supplied to the AD converter and approx. Ubat is measured again as a measured value. On the side of the control unit CU2, a measurement voltage would then be measured, which would be in the lower error range area, because the measured voltage is pulled to ground by the resistor R3, which is connected in the normal case. For this measurement, too, a corresponding error code would be entered into the error memory ERR of the control unit CU2. Now let us consider the case where the contacting of the shield on both sides is correct, but the control unit CU2 changes to a fault state. The switch S2 is opened by the microcontroller MCU when the control unit CU2 enters a fail-safe state. Because the resistor R3 is thus switched away from ground, the measurement voltage increases compared to the normal case and will be in the range RA2. Thus, it can be stated that CU2 is in the fault state if the measuring voltage is in the range RA2. At the same time, the statement can be made that the shield is correctly contacted on both sides. If the control unit CU2 is in proper operation, R3 is connected to ground. The measurement voltage drops into the range RA3. It can therefore be said that the shield is properly contacted on both sides and that the control unit CU2 is in a safe condition.

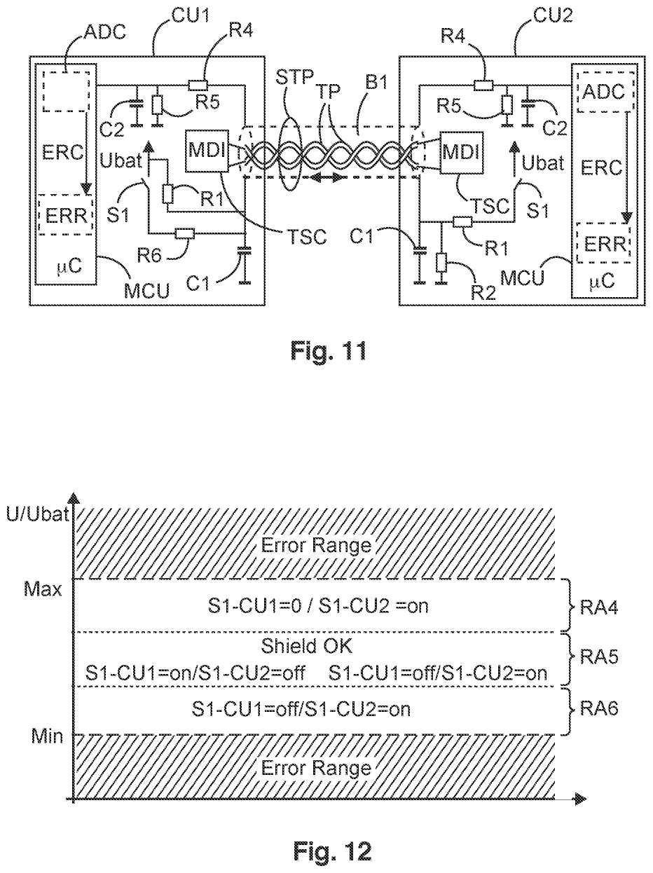

FIG. 11 shows an embodiment in which switching options were added to the circuits EC1 of the control units CU1 and CU2. This allows different voltage levels to be applied to the cable shield. For this purpose, the circuit EC1 of control unit CU1 was modified in such a way that a resistor R6 in parallel with R1 can be connected with the switch S1 instead of the resistor R1. In the case of circuit EC1 of control unit CU2, switch S1 remains unchanged compared to FIG. 7. However, the switch S2 and the resistor R3 are omitted. This can be used to signal various additional information in both directions. In the event that the communication via the twisted two-wire cable TP fails, the voltage level on the cable shield SD can be used to signal the status of the control unit connected on the opposite side. An example concerns the signaling of the information that the safety-relevant functions are available in the control unit and continue to be carried out autonomously. To signal this information, switch S1 would be closed in control unit CU2. For signaling this information, an additional line (ABS fault indication) is provided for this purpose in the case of brake control units currently used in trailer vehicles or PLC communication, corresponding to powerline communication, is prescribed. These solutions can be replaced by the measure described here. In the same way, additional information can be signaled by the control unit CU1 if the switch S1 on the side of the circuit EC1 in the control unit CU1 is closed.

FIG. 12 shows the corresponding division of the permissible voltage range into three ranges RA4, RA5, RA6. FIG. 12 also indicates the switching operations for which the measured voltage is in which range. The measured voltage is in the range RA4 when the switches S1 in both control units CU1 and CU2 are closed at the same time. The measured voltage is in the range RA5 when the switches S1 are closed on one side and open on the other side. The measured voltage is in the range RA6 if the switches S1 remain open on both.

In order to transmit further information in the sense of a plurality of bits, pulse width modulation PWM can be used in a simple variant. This determines how long a switch S1 is closed on each side. For asynchronous operation, a start bit and a stop bit can also be transmitted. However, it must be noted that the bandwidth for transmitting information should remain below 10 kHz, a range of 1 kHz is preferred. The problem is that the transmission of information on the shielding of the cable creates interference radiation, which must not lead to malfunctions in the surrounding electronic assemblies. In this case, it would be advantageous if a soft “modulation” were to be carried out when switching switches S1 and S2, because correspondingly higher frequencies would be generated as interference radiation in the case of sharp square wave signals.

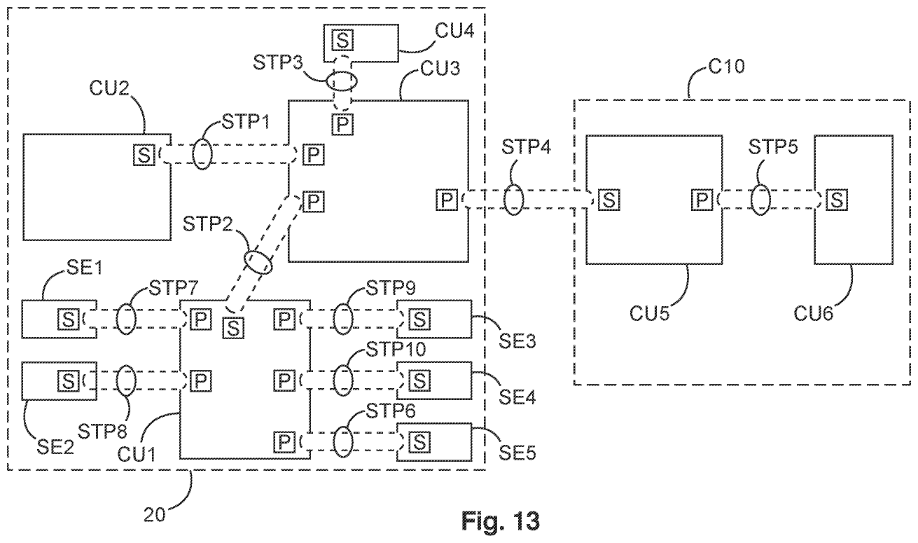

FIG. 13 shows the structure of an exemplary vehicle electronic system of the towing vehicle 20 and the trailer vehicle 10, both of which can communicate with each other via a connection cable STP4. In the case of the towing vehicle 20, only the electronic processing devices gateway device CU3, environment acquisition device CU1 and onboard communication module CU2 are shown as examples to illustrate the networking principle. The electronic control units of a powertrain as well as the processing units and the electronic control units of a driver assistance system DA and an infotainment system are provided. 3 camera sensors SE3 to SE5 and a radar sensor SE1 and a lidar sensor SE2 are connected to the environment acquisition device CU1. Another device CU4 of the infotainment system is connected to the gateway device CU3. In the case of the vehicle electronics system of the trailer vehicle 10, only a gateway device CU5 and the brake control unit CU6 are shown. However, it is also possible to provide additional electronic devices here. As an example of another electronic device, a reversing camera is mentioned. All communication connections with the cables STP1 to STP10 between the control units and between the sensors and the environment acquisition device CU1 are implemented as automotive Ethernet connections in one of the variants, in particular 100Base-T1 and 1000Base-T1, for which twisted-pair connection cables are used with simple shielding, for example. For all these point-to-point connections, it is shown which communication partner is configured as the primary device and which communication partner is configured as the secondary device. The configuration as a primary device is marked with the symbol P and the configuration as a secondary device with the symbol S.

All examples mentioned herein, as well as conditional formulations, are to be understood without limitation to such specifically cited examples. For example, it will be recognized by persons skilled in the art that the block diagram shown here represents a conceptual view of an exemplary circuit arrangement. Similarly, it can be seen that a flowchart, state transition diagram, pseudocode, and the like represent different variants for representing processes that are essentially stored in computer-readable media and thus can be executed by a computer or processor.

It should be understood that the disclosed method and related devices can be implemented in various forms of hardware, software, firmware, special processors, or a combination thereof. Specialty processors can include application-specific integrated circuits (ASICs), reduced instruction set computers (RISC), and/or field programmable gate arrays (FPGAs). Preferably, the disclosed method and device will be implemented as a combination of hardware and software. The software will preferably be installed as an application program on a program storage device. Typically, it is a machine based on a computer platform that has hardware, such as one or more central processing units (CPU), random access memory (RAM), and one or more input/output (I/O) interfaces. An operating system is also typically installed on the computer platform. The various processes and functions described here can be part of the application program or a part that is implemented by the operating system.

The disclosure is not limited to the exemplary embodiments described herein. There is room for various adjustments and modifications which the person skilled in the art would consider on the basis of his or her specialist knowledge as also pertaining to the disclosure.

While subject matter of the present disclosure has been illustrated and described in detail in the drawings and foregoing description, such illustration and description are to be considered illustrative or exemplary and not restrictive. Any statement made herein characterizing the invention is also to be considered illustrative or exemplary and not restrictive as the invention is defined by the claims. It will be understood that changes and modifications may be made, by those of ordinary skill in the art, within the scope of the following claims, which may include any combination of features from different embodiments described above.

The terms used in the claims should be construed to have the broadest reasonable interpretation consistent with the foregoing description. For example, the use of the article “a” or “the” in introducing an element should not be interpreted as being exclusive of a plurality of elements. Likewise, the recitation of “or” should be interpreted as being inclusive, such that the recitation of “A or B” is not exclusive of “A and B,” unless it is clear from the context or the foregoing description that only one of A and B is intended. Further, the recitation of “at least one of A, B and C” should be interpreted as one or more of a group of elements consisting of A, B and C, and should not be interpreted as requiring at least one of each of the listed elements A, B and C, regardless of whether A, B and C are related as categories or otherwise. Moreover, the recitation of “A, B and/or C” or “at least one of A, B or C” should be interpreted as including any singular entity from the listed elements, e.g., A, any subset from the listed elements, e.g., A and B, or the entire list of elements A, B and C.

REFERENCE SIGN LIST (PART OF THE DESCRIPTION)

| | |
|---|---|
| 10 | trailer vehicle |
| 12 | support |
| 20 | towing vehicle |
| 22 | coupling element |
| 24 | drive unit |
| 26 | service brake |
| ADC | AD converter |
| ADI | AD converter Input |
| B1 | communication connection |
| C1-C2 | capacitors |
| C1a-C1d | capacitors |
| CU1 | environment acquisition device, first communication unit |
| CU2 | onboard communication device, second communication unit |
| CU3 | 1st gateway device |
| CU4 | infotainment unit |
| CU5 | 2nd gateway device |
| CU6 | electronic brake control unit |
| EC1 | 1st circuit |
| EC2 | 2nd circuit |
| ERC | error signal |
| ERR | error memory |
| MCU | microcontroller |
| PL | plug |
| R1-R6 | resistors |
| RA1-RA6 | permissible measured voltage ranges |
| S1-S2 | switches |
| SC | socket |
| SD | cable shield |
| STP | bus connection cable |
| STP1-STP10 | more bus connection cables |
| TSC | bus transceiver |

1. A device for checking the function of a cable shield of a wired communication connection between two communication partners which communicate by the wired communication connection, comprising:
a first electrical circuit is provided in at least one of the communication partners, by which a test voltage can be applied to the cable shield; and
a second electrical circuit is provided in one or another of the communication partners, which feeds the applied test voltage to a measured value acquisition unit, which takes a measurement of the test voltage and generates an error signal if a test voltage has been measured that is outside a permissible value range or outside one of a plurality of permissible value ranges.

2. The device as claimed in claim 1, wherein in the first electrical circuit switching devices are provided which can switch the application of the test voltage on and off and/or wherein in the first electrical circuit switching devices are provided which can switch a dissipation of the test voltage to the electrical ground on and off.

3. The device as claimed in claim 1, wherein one or both communication partners contain an electronic control device that is used to control the first or second switching device.

4. The device as claimed in claim 3, wherein the electronic control device is a programmable electronic control device in the form of a microcontroller, and wherein the measured values acquisition unit is an analog-to-digital converter, as a measured values acquisition means which digitally acquires the voltage value of the test voltage.

5. The device as claimed in claim 1, wherein in the first electrical circuit contact pins are distributed around a circumference of the cable shield, which press against the contact surfaces of the cable shield in an area of the connector of a cable of the communication connection when it is plugged into a corresponding socket of the communication partner, wherein the contact pins are each connected to ground potential with a capacitor, and wherein the capacitors have different capacitance values.

6. The device as claimed in claim 5, wherein the cable of the communication connection has a number of twisted wire pairs through which the bus signals are transmitted.

7. The device as claimed in claim 8, wherein the cable of the communication connection is a cable of type S/FTP, corresponding to “screened foiled twisted pair” according to standard ISO/IEC-11801E: S/FTP and with only one pair of twisted wires encased in aluminum foil and a wire mesh as an external shield.

8. The device as claimed in claim 1, wherein the transmission of data through the cable of the communication connection is carried out according to the communication standard IEEE 802.3 bp, corresponding to 1000BaseT1 type B.

9. A method for checking the function of a cable shield of a wired communication connection between two communication partners which communicate by the wired communication connection, the method comprising:
applying a test voltage to the cable shield by one communication partner;
measuring a test voltage on the cable shield at one or another communication partner;
evaluating the measurements in one or the other communication partner; and
generating an error signal in one or the other communication partner if the test voltage could not be measured or a test voltage was measured that is outside a permissible value range or outside one of a plurality of permissible value ranges.

10. An electronic processing unit configured as a one of the communication partners in the device as claimed in claim 1, comprising:
a first electrical circuit by which a test voltage can be applied to the cable shield and/or
a second electrical circuit which supplies the applied test voltage to a measured values acquisition unit, which takes a measurement of the test voltage and generates an error signal if the test voltage could not be measured or a test voltage has been measured that is outside a permissible value range or outside one of a plurality of permissible value ranges.

11. The electronic processing unit as claimed in claim 10, wherein in the first electrical circuit first switching devices are provided which can switch an application of the test voltage on and off and/or wherein in the first electrical circuit second switching devices are provided which are capable of switching on and off the dissipation of the test voltage to the electrical ground.

12. The electronic processing unit as claimed in claim 10, wherein in the first electrical circuit contact pins distributed around a circumference of the cable shield which press against contact surfaces of the cable shield in an area of the connector of a cable of the communication connection, when it is plugged into a corresponding socket of the communication partner, and
wherein the contact pins are connected to ground potential by respective capacitors which have different capacitance values.

13. The electronic processing unit as claimed in claim 10, wherein the electronic processing unit contains an electronic control device configured to control the first or second switching device.

14. The electronic processing unit as claimed in claim 11, wherein the electronic control device is configured to control the first switching devices and/or the second switching devices such that additional information, in particular about the state of the electronic processing unit or an activity signal of the electronic processing unit or generally serial data, in addition to the data transmitted through the communication connection, is transmitted unidirectionally or bidirectionally.

15. The electronic processing unit as claimed in claim 13, wherein the electronic control device is a programmable control device in the form of a microcontroller.

16. A vehicle comprising:
a towing vehicle;
a trailer vehicle; and
the device as claimed in claim 1,
wherein one communication partner is an electronic processing unit in the towing vehicle and the other communication partner is an electronic processing unit in the trailer vehicle, both of which are connected to each other by a cable of the communication connection.
